(19) United States
(12) Patent Application Publication
(10) Pub. No.: US 2025/0129930 A1
(43) Pub. Date: Apr. 24, 2025

(54) LIGHT-EMITTING MODULE AND SMARTPHONE

(71) Applicant: NICHIA CORPORATION, Anan-shi (JP)

(72) Inventors: Tsuyoshi OKAHISA, Tokushima-shi (JP); Norimasa YOSHIDA, Komatsushima-shi (JP)

(73) Assignee: NICHIA CORPORATION, Anan-shi (JP)

(21) Appl. No.: 18/917,233

(22) Filed: Oct. 16, 2024

(30) Foreign Application Priority Data
Oct. 24, 2023 (JP) 2023-182820
Sep. 20, 2024 (JP) 2024-164283

(51) Int. Cl. F21V 33/00; F21V 3/06; F21V 5/04; F21V 17/06

(52) U.S. Cl. CPC F21V 33/0052; F21V 3/06; F21V 5/04; F21V 17/06

(57) ABSTRACT

A light-emitting module includes: a substrate; a light source disposed on the substrate; an electronic component disposed on the substrate and separated from the light source; and a first light-transmissive member including a first lens and a first support, and covering the light source and the electronic component, the first support supporting the first lens and including a light diffusing substance. A light diffusivity of the first support is higher than a light diffusivity of the first lens. The first lens overlaps the light source and the first support overlaps the electronic component in a top view.

### CROSS-REFERENCE TO RELATED APPLICATIONS

This application is based on and claims priority to Japanese Patent Application No. 2023-182820, filed on Oct. 24, 2023, and Japanese Patent Application No. 2024-164283, filed on Sep. 20, 2024. The entire contents of these applications are incorporated herein by reference.

### TECHNICAL FIELD

The present disclosure relates to a light-emitting module and a smartphone.

### BACKGROUND

Light-emitting modules including light-emitting elements such as light-emitting diodes (LEDs) have been widely used. For example, Japanese Patent Publication No. 2020-181027 describes a light-emitting module including a substrate; a light-emitting element and an electronic component which are disposed on the substrate; a lens disposed apart from the light-emitting element and the electronic component to face the light-emitting element and the electronic component; and a covering member such as a masking resin disposed between the lens and the electronic component and including a coloring agent.

### SUMMARY

It is an object of one embodiment of the present disclosure to provide a light-emitting module that can be easily assembled.

A light-emitting module according to one embodiment of the present disclosure includes a substrate; a light source disposed on the substrate; an electronic component disposed on the substrate and separated from the light source; and a first light-transmissive member that includes a first lens and a first support and covers the light source and the electronic component, the first support supporting the first lens and including a light diffusing substance, wherein a light diffusivity of the first support is higher than a light diffusivity of the first lens, and the first lens overlaps the light source and the first support overlaps the electronic component in a top view.

### BRIEF DESCRIPTION OF THE DRAWINGS

FIG. 1 is a schematic top view illustrating a light-emitting module according to a first embodiment;

FIG. 2A is a schematic cross-sectional view taken through line IIA-IIA of FIG. 1;

FIG. 2B is a schematic cross-sectional view taken through line IIB-IIB of FIG. 1;

FIG. 3 is a schematic top view illustrating a light source included in the light-emitting module according to the first embodiment;

FIG. 4 is a schematic cross-sectional view taken through line IV-IV in FIG. 3;

FIG. 5 is a schematic cross-sectional view of a light-emitting module according to a first modification of the first embodiment;

FIG. 6 is a schematic cross-sectional view illustrating a light-emitting module according to a second modification of the first embodiment;

FIG. 7 is a schematic top view of a light-emitting module according to a second embodiment;

FIG. 8 is a schematic cross-sectional view taken through line VIII-VIII of FIG. 7;

FIG. 9 is a schematic rear view illustrating a smartphone according to a third embodiment;

FIG. 10 is a schematic cross-sectional view of a light-emitting module included in the smartphone according to the third embodiment, and is a schematic cross-sectional view taken through line X-X of FIG. 9;

FIG. 11 is a schematic cross-sectional view of a first modification of the light-emitting module included in the smartphone according to the third embodiment; and

FIG. 12 is a schematic cross-sectional view of a second modification of the light-emitting module included in the smartphone according to the third embodiment.

### DETAILED DESCRIPTION

Light-emitting modules according to embodiments of the present disclosure will be described in detail with reference to the accompanying drawings. The embodiments described below exemplify the light emitting modules to embody the technical ideas of the invention, but the invention is not limited to the described embodiments. In addition, unless otherwise specified, the dimensions, materials, shapes, relative arrangements, and the like of components described in the embodiments are not intended to limit the scope of the present invention thereto, but are described as examples. The sizes, positional relationships, and the like of members illustrated in the drawings may be exaggerated for clearer illustration. Further, in the following description, the same names and reference numerals refer to the same or similar members, and a detailed description thereof will be omitted as appropriate. An end view illustrating only a cut surface may be used as a cross-sectional view.

In the drawings, directions may be indicated by an X-axis, a Y-axis, and a Z-axis. The X-axis, the Y-axis, and the Z-axis are orthogonal to one another. An X direction along the X-axis and a Y direction along the Y-axis indicate directions along a light-emitting surface of a light-emitting part included in each of the light-emitting modules according to the embodiments. A Z direction along the Z-axis indicates a direction orthogonal to the light-emitting surface. That is, the light-emitting surface of the light-emitting part is parallel to the XY plane, and the Z-axis is orthogonal to the XY plane.

A direction indicated by an arrow in the X direction is referred to as a +X side, and a direction opposite to the +X side is referred to as a −X side. A direction indicated by an arrow in the Y direction is referred to as a +Y side, and a direction opposite to the +Y side is referred to as a −Y side. A direction indicated by an arrow in the Z direction is referred to as a +Z side, and a direction opposite to the +Z side is referred to as a −Z side. In the embodiments, the light-emitting part included in each of the light-emitting modules are configured to emit light in the +Z as an example. Further, the phrase “in a top view” as used in the embodiments refers to viewing an object from the light emission surface side of a first lens included in the light-emitting modules according to the embodiments. In the present specification, the phrase “in a top view” may be used to describe, in addition to a portion that can be directly seen from above, a portion that cannot be directly seen from above as if it can be seen from above. A light emission surface of the first lens refers to a surface of the first lens through which light emitted from a light source included in the light-emitting module according to the embodiments is emitted. However, these expressions do not limit the orientations of the light-emitting modules according to the embodiments during use, and the orientations of the light-emitting modules according to the embodiments are discretionary.

Further, in the present specification, a surface of the object as viewed from the +Z side is referred to as an “upper surface,” and a surface of the object as viewed from the −Z side is referred to as a “lower surface.” In the embodiments described below, each of “along the X-axis,” “along the Y-axis,” and “along the Z-axis” includes a case where the object is at an inclination within a range of +10° with respect to the corresponding one of the axes. Further, in the embodiments, the term “orthogonal” may include a deviation within +10° with respect to 90°.

Further, in the present specification and the claims, if there are multiple components and these components are to be distinguished from one another, the components may be distinguished by adding terms “first,” “second,” and the like before the names of the components. Further, objects to be distinguished may be different between the specification and the claims. Therefore, even if a component recited in the claims is denoted by the same reference numeral as that of a component described in the present specification, an object specified by the component recited in the claims is not necessarily identical with an object specified by the component described in the specification.

For example, if components are distinguished by the ordinal numbers “first,” “second,” and “third” in the specification, and components with “first” and “third” or components with “first” and without a specific ordinal number in the specification are described in the claims, these components may be distinguished by the ordinal numbers “first” and “second” in the claims for ease of understanding. In this case, the components with “first” and “second” in the claims respectively refer to the components with “first” and “third” or the components with “first” and without a specific ordinal number in the specification. This rule is applied not only to components but also other objects in a reasonable and flexible manner.

### First Embodiment

### Example Configuration of Light-Emitting Module According to First Embodiment

### Overall Configuration

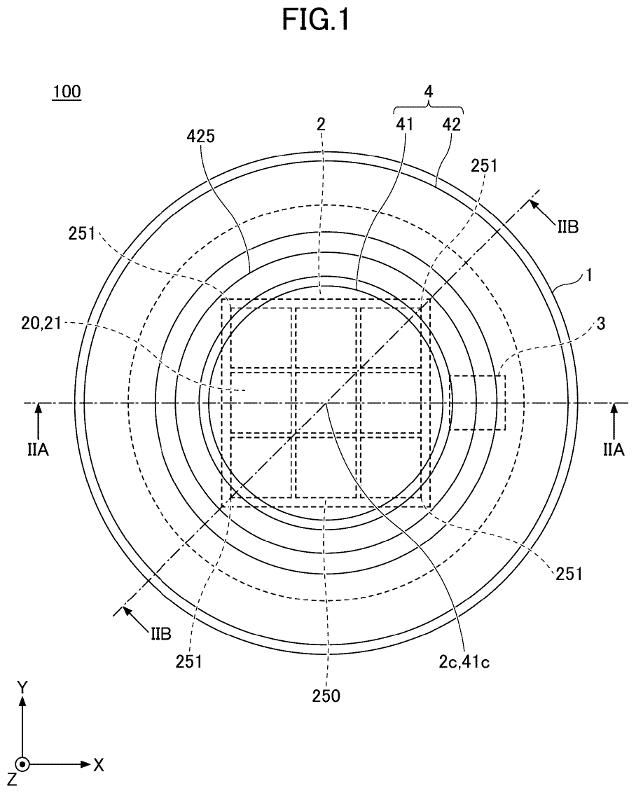

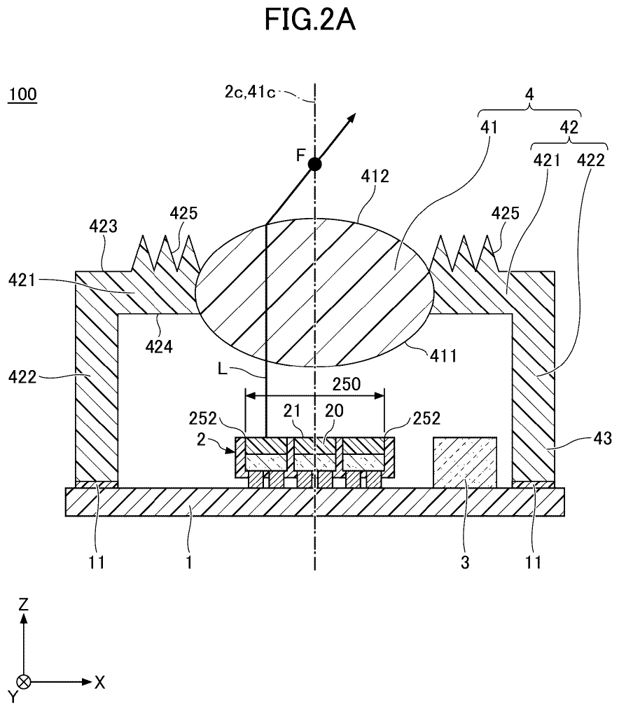

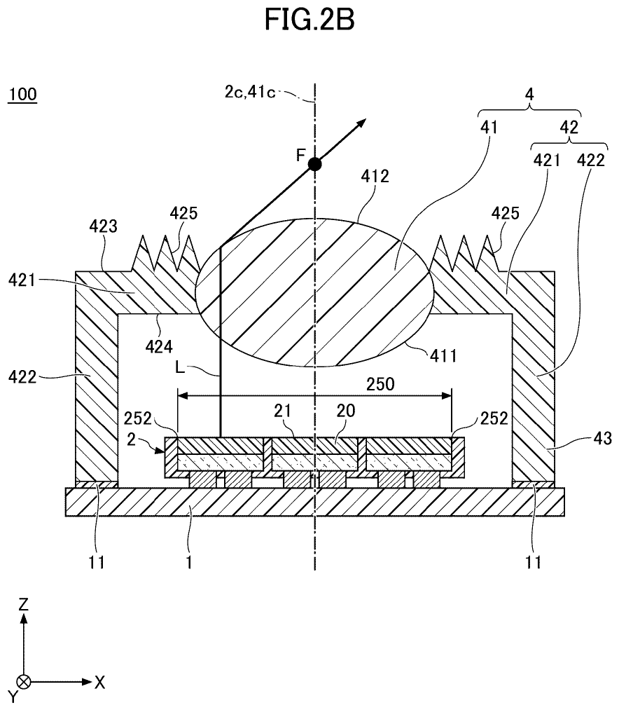

The overall configuration of a light-emitting module according to a first embodiment will be described with reference to FIGS. 1, 2A, and 2B. FIG. 1 is a schematic top view illustrating an example of a light-emitting module 100 according to the first embodiment. FIG. 2A is a schematic cross-sectional view taken through line IIA-IIA of FIG. 1. FIG. 2B is a schematic cross-sectional view taken through line IIB-IIB of FIG. 1.

As illustrated in FIGS. 1 and 2A, the light-emitting module 100 includes a substrate 1, a light source 2 disposed on the substrate 1, and an electronic component 3 disposed on the substrate 1 and separated from the light source 2. In addition, the light-emitting module 100 includes a first light-transmissive member 4 that includes a first lens 41 and a first support 42 and covers the light source 2 and the electronic component 3. The first support 42 supports the first lens 41, and includes a light diffusing substance. The light diffusivity of the first support 42 is higher than the light diffusivity of the first lens 41. The first lens 41 overlaps the light source 2 and the first support 42 overlaps the electronic component 3 in a top view.

In the light-emitting module 100, the first support 42 and the electronic component 3 overlap each other in a top view, thereby making it possible for the electronic component 3 to be less visually recognizable from the outside of the light-emitting module 100 by the light diffusivity of the first support 42. Accordingly, a process of disposing a masking resin on the electronic component 3 to make the electronic component 3 less visually recognizable from the outside can be omitted. If the process of disposing a masking resin on the electronic component 3 is omitted, there is no risk of the masking resin accidentally coming into contact with the light source 2. Therefore, according to the present embodiment, a light-emitting module 100 that can be easily assembled can be provided. Further, by making the electronic component 3 less visually recognizable from the outside of the light-emitting module 100, the aesthetic appearance of the light-emitting module 100 can be improved.

Further, in the example illustrated in FIGS. 1, 2A, and 2B, the first support 42 includes a light diffusing substance 43 inside the first support 42. As the light diffusing substance 43, titanium oxide, barium titanate, aluminum oxide, silicon oxide, or the like can be used. In the light-emitting module 100, the first support 42 includes the light diffusing substance 43 therein, and thus light diffusivity can be easily imparted to the first support 42.

Further, in the example illustrated in FIGS. 1, 2A, and 2B, the first lens 41 and the first support 42 constitute a formed body in which the first lens 41 and the first support 42 are directly bonded to each other at the interface therebetween. More specifically, the first lens 41 includes a resin having light transmissivity. The first support 42 includes a resin having light transmissivity and containing the light diffusing substance 43. It is preferable that the electronic component 3 is less visually recognizable from the outside of the light-emitting module 100. The light diffusivity of the first support 42 is higher than the light diffusivity of the first lens 41. The light diffusivity of the first support 42 being higher than the light diffusivity of the first lens 41 means that, for example, the haze value of the first support 42 is higher than the haze value of the first lens 41. The haze value of the first support 42 is 10% or more and 90% or less. The haze value of the first lens 41 is less than 10%, and is preferably 5% or less. The first lens 41 may include a resin containing a light diffusing substance 43. In this case, the content of the light diffusing substance 43 in the first lens 41 is smaller than the content of the light diffusing substance 43 in the first support 42. As will be described later, if the electronic component 3 includes an external light sensor, the first support 42 needs to have light transmissivity such that the external light sensor receives external light that has entered the light-emitting module 100 from the outside of the light-emitting module 100. Therefore, each of the light transmissivity of the first lens 41 and the light transmissivity of the first support 42 preferably has a property of transmitting 20% or more and 85% or less, and preferably 40% or more and 70% or less of light incident on the first lens 41 from the outside. In the present embodiment, the light transmittance of the first support 42 is lower than the light transmittance of the first lens 41. However, the light transmittance of the first support 42 may be equal to the light transmittance of the first lens 41, as long as the electronic component 3 is less visually recognizable from the outside of the light-emitting module 100 by using the light diffusivity of the first support 42 to scatter external light or light emitted from the light source. The resin, serving as a base material of the first support 42, contains the light diffusing substance 43, and may be the same as or different from the resin constituting the first lens 41. The first lens 41 and the first support 42, constituting the formed body directly bonded at the interface therebetween, can be manufactured by, for example, double-molding using a molding die. In the example illustrated in FIGS. 1, 2A, and 2B, the light-emitting module 100 can be easily assembled by using the first lens 41 and the first support 42 constituting the formed body directly bonded at the interface therebetween.

Further, in the light-emitting module 100, the first support 42 may overlap the outer edge of a light emission region 250 of the light source 2 in a top view. In the example illustrated in FIG. 1, the first support 42 overlaps corner portions 251 of the outer edge of the light emission region 250 in a top view. However, the first support 42 may overlap linear outer edge portions 252 excluding the corner portions 251 of the light emission region 250 illustrated in FIGS. 1 and 2B in a top view. That is, the outer edge of the light emission region 250 includes the corner portions 251 of the light emission region 250 and the linear outer edge portions 252 of the light emission region 250. The first support 42 may overlap either the corner portions 251 or the linear outer edge portions 252 of the light emission region 250, or may overlap both the corner portions 251 and the linear outer edge portions 252 of the light emission region 250.

The light source 2 includes at least one light-emitting surface 21, and the light emission region 250 is a region including the at least one light-emitting surface 21. If the light source 2 includes one light-emitting surface 21, the light emission region 250 is a region surrounded by the outer edge of the one light-emitting surface 21. In this case, the outer edge of the light emission region 250 corresponds to the outer edge of the one light-emitting surface 21. If the light source 2 includes a plurality of light-emitting surfaces 21, the light emission region 250 is a region connecting the outermost edges of light-emitting surfaces 21 located outermost in a top view. In this case, the outer edge of the light emission region 250 corresponds to a annular-shaped line formed by connecting the outermost edges of light-emitting surfaces 21 located outside in a top view. The annular-shaped line corresponding to the outer edge of the light emission region 250 is not limited to a circular shape or an elliptical shape as long as the start point and the end point coincide with each other. Alternatively, the shape of the annular-shaped line in a plan view may be a annular-shaped line including a straight line and an arc-shaped line, or may be a polygonal annular-shaped line. In the example illustrated in FIGS. 1, 2A, and 2B, the light source 2 includes nine light-emitting parts 20, and the nine light-emitting parts 20 each include a light-emitting surface 21. The nine light-emitting surfaces 21 are arranged in a matrix of three rows and three columns on an imaginary plane (for example, the XY plane). In the example illustrated in FIGS. 1, 2A, and 2B, the light emission region 250 includes the nine light-emitting surfaces 21. The shape of the outer edge of the light emission region 250 is a substantially rectangular shape.

A center 2c of the light emission region 250 coincides with an optical axis 41c of the first lens 41 in a top view. The corner portions 251 of the light emission region 250 are located far from the optical axis 41c of the first lens 41. Thus, there would be a possibility that a portion of light emitted from the light-emitting parts 20 would not be incident on the first lens 41 and cause stray light. The stray light would deteriorate the quality of light emitted from the light-emitting module 100. The quality of light emitted from the light-emitting module 100 refers to at least one of performance or functions required for the light emitted from the light-emitting module 100. For example, if stray light is generated in the light-emitting module 100, there would be a possibility that the positional accuracy, the illuminance, the uniformity of illuminance distribution, and the like of light emitted from the light-emitting module 100 onto an irradiation surface would not meet requirements.

Conversely, in the example illustrated in FIGS. 1, 2A, and 2B, the first support 42 overlaps the corner portions 251 in a top view, and thus light that is emitted from the corner portions 251 and their vicinities of the light emission region 250 and travels toward the first support 42 is scattered by the first support 42. Accordingly, the light scattered by the first support 42 is less likely to be included in the light emitted from the light-emitting module 100, and the light emitted from the corner portions 251 and their vicinities can be suppressed from being stray light.

In the example illustrated in FIG. 1, the outer shape of the light-emitting module 100 in a top view is a substantially circular shape. However, the shape of the light-emitting module 100 in a top view may be a substantially rectangular shape, a substantially elliptical shape, a substantially polygonal shape, or the like. The light source 2 is mounted on the upper surface (surface on the +Z side) of the substrate 1. The light source 2 emits light from the light-emitting surfaces 21 included in the nine light-emitting parts 20 toward the first lens 41. The number of the light-emitting parts 20 included in the light source 2 is not limited to nine, and may be at least one.

The light-emitting module 100 may turn on the nine light-emitting parts 20 individually or in groups. The light-emitting module 100 can increase the contrast on the irradiation surface irradiated with light from the light source 2 by individually turning on the nine light-emitting parts 20 or turning on the nine light-emitting parts 20 by groups, with desired brightness. The light-emitting module 100 can perform partial irradiation on the illumination surface by individually turning on the nine light-emitting parts 20 or turning on the nine light-emitting parts 20 by groups. The “partial irradiation” means that a portion of the irradiation surface is irradiated with light.

In the partial irradiation, the outer edge of irradiation light is preferably sharply defined such that light with which a portion of the irradiation surface is irradiated is made conspicuous. That is, it is preferable to have a large difference in illuminance of irradiation light between a desired region to be irradiated with light and a region other than the desired region. In other words, it is preferable that the amount of stray light around irradiation light is small in a desired region of the irradiation surface to be irradiated with light. By reducing the amount of stray light on the irradiation surface, the light-emitting module 100 can reduce the amount of light with which a region other than a desired region is irradiated, while irradiating the desired region with light. Accordingly, a difference in illuminance of irradiation light between a desired region to be irradiated with light and a region other than the desired region can be increased, and the light with which the desired region is irradiated can be made conspicuous.

If the light-emitting module 100 is used as a flash light source when an imaging device captures an image, the light-emitting module 100 can emit light by switching between a wide-angle mode and a narrow-angle mode. The wide-angle mode is an operation mode of the light-emitting module 100 in which all the light-emitting parts 20 emit light. The narrow-angle mode is an operation mode of the light-emitting module 100 in which only light-emitting parts 20 located at and near the center of the light emission region 250 emit light and light-emitting parts 20 located near the outer edge portions 252 of the light emission region 250 do not emit light. In the narrow-angle mode, the light distribution angle is narrower than that in the wide-angle mode. In the light emitting module 100, irradiation light can be switched in accordance with the wide-angle mode or the narrow-angle mode. Thus, by using light emitted from the light-emitting module 100, the imaging device can capture an image in accordance with a photographing mode such as close-up photography or telephoto photography.

### Detailed Configuration

In the example illustrated in FIG. 1, the substrate 1 is a plate-shaped member having a substantially circular shape in a top view. The substrate 1 includes wiring on which the light source 2 and various electronic components can be mounted. The shape of the substrate 1 in a top view may be a substantially rectangular shape, a substantially elliptical shape, a substantially polygonal shape, or the like.

As a base material of the substrate 1, an insulating material is preferably used, and also a material that does not easily transmit light emitted from the light-emitting parts 20, external light, or the like is preferably used. Further, as the base material of the substrate 1, a material having a certain strength is preferably used. Specifically, as the base material of the substrate 1, a ceramic such as alumina, aluminum nitride, mullite, or silicon nitride, or a resin such as a phenol resin, an epoxy resin, a polyimide resin, a bismaleimide-triazine resin (BT resin), polyphthalamide, or a polyester resin can be used.

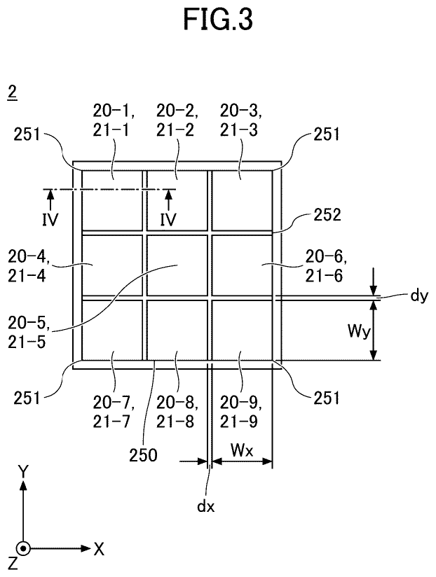

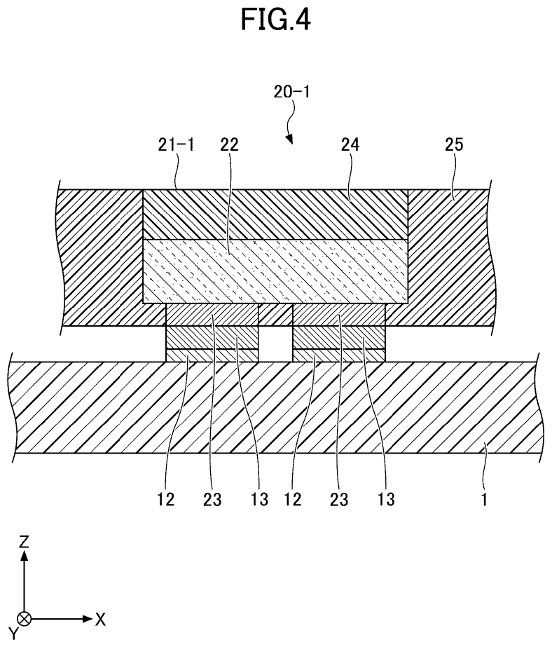

The light source 2 will be separately described later in detail with reference to FIGS. 3 and 4.

The electronic component 3 includes at least one of a Zener diode, a thermistor, a capacitor, an external light sensor, or the like. In the example illustrated in FIGS. 1 and 2A, the electronic component 3 is an external light sensor.

The first light-transmissive member 4 is a member that transmits light L from the light source 2. The first light-transmissive member 4 is disposed so as to cover the light source 2 and the electronic component 3. In the example illustrated in FIG. 1, the first light-transmissive member 4 has a substantially circular shape in a top view. However, the first light-transmissive member 4 may have a substantially elliptical shape, a substantially rectangular shape, a substantially polygonal shape, or the like in a top view.

The first light-transmissive member 4 includes the first lens 41 and the first support 42 as described above. The first light-transmissive member 4 includes at least one of a resin material such as a polycarbonate resin, an acrylic resin, a silicone resin, or an epoxy resin, or a glass material, which have light transmissivity with respect to the light L emitted from the light source 2. In the example illustrated in FIGS. 1, 2A, and 2B, the first lens 41 and the first support 42 are an integrated member without using an adhesive member. However, the first lens 41 and the first support 42 may be separate members bonded to each other by an adhesive member.

In the example illustrated in FIGS. 1, 2A, and 2B, the first lens 41 is a biconvex lens. A first convex surface 411 and a second convex surface 412 of the first lens 41 form a biconvex lens. However, the first lens 41 is not limited to a biconvex lens, and may be a plano-convex lens, a biconcave lens, a plano-concave lens, a Fresnel lens, an array lens, a meniscus lens, an aspherical lens, a cylindrical lens, or the like.

In the example illustrated in FIG. 2A, the distance between the surface (first convex surface 411) of the first lens 41 on a light source 2 side and the light source 2 increases as the distance from the optical axis 41c of the first lens 41 increases. The distance between the first convex surface 411 and the light source 2 is a distance in a direction (the Z direction in FIG. 2A) along the optical axis 41c of the first lens 41. Because the distance between the first convex surface 411 and the light source 2 increases as the distance from the optical axis 41c of the first lens 41 increases, the light L emitted from the light source 2 is incident on the first convex surface 411, is made to be close to parallel light, and then exits the second convex surface 412. Accordingly, the distribution of light emitted from the light-emitting module 100 can be controlled mainly by the shape of the second convex surface 412, and thus the distribution of light emitted from the light-emitting module 100 can be easily controlled.

In the example illustrated in FIG. 2A, the light L from the light source 2 is once focused on a focal point F by the first convex surface 411 and the second convex surface 412, and then emitted onto the irradiation surface as divergent light. The focal point F overlaps the center 2c of the light emission region 250 in a top view. In the first lens 41 including the convex lens, the focal point F is on the +Z side of the first lens 4. The light L from each of the plurality of light-emitting parts 20 is concentrated on the focal point F, and then spreads. Accordingly, for example, in a case where the light-emitting module 100 is installed in a smartphone or the like, the light L emitted from the light-emitting module 100 can be suppressed from being blocked by a housing of the smartphone or the like. Further, the light L from the light source 2 can be efficiently emitted through the first lens 41.

In the example illustrated in FIG. 1, the first lens 41 has a substantially circular shape in a top view. However, the first lens 41 may have a substantially rectangular shape, a substantially elliptical shape, a substantially polygonal shape, or the like in a top view. Further, the first lens 41 may have a rotational symmetry shape in a top view. Considering that an imaging range of a general imaging device is substantially rectangular, it is preferable that the shape of the first lens 41 in a top view is a four-fold rotational symmetry shape or a two-fold rotational symmetry shape. In the first lens 41, the radii of curvature of the first convex surface 411 and the second convex surface 412, the magnitude relationship between the radii of curvature, the thickness of the lens, and the like can also be appropriately changed.

The first support 42 supports the first lens 41 such that the first lens 41 is disposed above the light source 2. In the example illustrated in FIG. 2A, the first support 42 includes an upper portion 421 and a first cylindrical portion 422. The upper portion 421 is a portion that supports the first lens 41 from the outside in a top view. The upper portion 421 includes an upper surface 423 and a lower surface 424 substantially parallel to the light-emitting surfaces 21 of the light source 2. The first cylindrical portion 422 is a circular annular portion located outward of the light source 2 and the electronic component 3 in a top view. The first cylindrical portion 422 is provided so as to extend downward at a position outward of the light source 2 and the electronic component 3. In the present embodiment, the first support 42 includes the first cylindrical portion 422, and the inner lateral surface or the outer lateral surface of the first cylindrical portion is not limited to a flat surface and may be a curved surface. Further, the upper surface 423 and the lower surface 424 of the upper portion 421 may be inclined so as to approach the light source 2 as the distance from the optical axis 41c of the first lens 41 increases. The upper portion 421 and the first cylindrical portion 422 are continuous with each other. The upper portion 421 and the first cylindrical portion 422 are an integral member without using an adhesive member. However, the upper portion 421 and the first cylindrical portion 422 may be separate members bonded to each other by an adhesive member. The first light-transmissive member 4 is disposed on the upper surface of the substrate 1 by disposing the first cylindrical portion 422 of the first support 42 on the upper surface of the substrate 1 via an adhesive member 11 or the like.

In the light-emitting module 100, the first support 42 can have annular projection(s) 425 on at least one of the upper surface 423 or the lower surface 424 of the first support 42. In the example illustrated in FIG. 2A, the first support 42 has three annular projections 425 on the upper surface 423 of the upper portion 421. Each of the three annular projections 425 is a portion that protrudes from the upper surface 423 toward the side (for example, the +Z side) opposite to the side on which the light source 2 is located. The three annular projections 425 are arranged concentrically around the optical axis 41c of the first lens 41. The three concentric annular projections 425 have a sawtooth shape or a wave shape. The three annular projections 425 may have, for example, a Fresnel shape.

The number of annular projections 425 is not limited to three, and can be appropriately changed. For example, the light diffusivity of the first support 42 can be adjusted by increasing the number of annular projections 425 so as to increase the light diffusivity or by decreasing the number of annular projections 425 so as to decrease the light diffusivity. Further, if each of the projections 425 has an inclined surface with respect to the optical axis 41c of the first lens 41, the angle of inclination of the inclined surface may be adjusted. As used herein, the “inclined surface” refers to a surface including a flat surface or a curved surface having an inclination angle with respect to the optical axis 41c in a cross-sectional view of the first light-transmissive member 4 along the optical axis 41c of the first lens 41.

The first support 42 includes the annular projections 425, and thus has a higher light diffusivity than that of the first lens 41. Further, the annular projections 425 can be easily formed by molding or the like. Therefore, in the light-emitting module 100, light diffusivity can be easily imparted to the first support 42 by the annular projections 425. Further, the annular projections 425 are preferably symmetrical in a top view. Accordingly, as compared to when the first support 42 includes asymmetrical projections in a top view, irregularities in the appearance can be reduced, and thus the aesthetic appearance of the light-emitting module 100 can be improved.

Next, a configuration of the light source 2 included in the light-emitting module 100 will be described with reference to FIGS. 3 and 4. FIG. 3 is a schematic top view illustrating an example of the light source 2. FIG. 4 is a schematic cross-sectional view taken through line IV-IV in FIG. 3.

In the example illustrated in FIG. 3, the light source 2 includes the nine light-emitting parts 20 having the respective light-emitting surfaces 21. Each of the nine light-emitting parts 20 emits light from a corresponding light-emitting surface 21 toward the first lens 41 provided above the light source 2. The light-emitting surfaces 21 refer to main light extraction surfaces of the light-emitting parts 20. The light emitted from each of the light-emitting parts 20 is preferably white light; however, the light may have a specific wavelength such as blue light. The wavelength and chromaticity of the light emitted from each of the light-emitting parts 20 may be appropriately selected according to the intended use of the light-emitting module 100.

In the example illustrated in FIG. 3, the light source 2 includes nine light-emitting parts 20-1, 20-2, 20-3, 20-4, 20-5, 20-6, 20-7, 20-8, and 20-9. The nine light-emitting parts 20 are arranged in the lengthwise direction or the widthwise direction or in a matrix in a top view. From another viewpoint, the nine light-emitting parts 20 are arranged along the X direction. Alternatively, the nine light-emitting parts 20 are arranged along the X direction and the Y direction orthogonal to the X direction. In the example illustrated in FIG. 3, the nine light-emitting parts 20 are arranged along the X direction and the Y direction.

The light-emitting part 20-1 has a light-emitting surface 21-1. The light-emitting part 20-2 has a light-emitting surface 21-2. The light-emitting part 20-3 has a light-emitting surface 21-3. The light-emitting part 20-4 has a light-emitting surface 21-4. The light-emitting part 20-5 has a light-emitting surface 21-5. The light-emitting part 20-6 has a light-emitting surface 21-6. The light-emitting part 20-7 has a light-emitting surface 21-7. The light-emitting part 20-8 has a light-emitting surface 21-8. The light-emitting part 20-9 has a light-emitting surface 21-9. It is preferable that 80% or more of the nine light-emitting surfaces 21-1 to 21-9 are disposed inward of the first lens 41 (inward relative to the outer shape of the first lens 41) in a top view. With this configuration, the size of the first lens 41 can be reduced and also good optical characteristics can be obtained. The light-emitting parts 20 respectively overlap the light-emitting surfaces 21 in a top view. Thus, the reference numeral of each of the light-emitting parts 20 and the reference numeral of a corresponding light-emitting surface 21 are written together in FIG. 3. Further, in the following description, if two or more components substantially coincide with each other or overlap each other, reference numerals may be written together.

A first width Wx represents the width of a light-emitting surface 21 in the X direction. A second width Wy represents the width of the light-emitting surface 21 in the Y direction. The first width Wx and the second width Wy are, for example, 30 μm or more and 2,000 μm or less, and preferably 100 μm or more and 1,000 μm or less. The first width Wx and the second width Wy may be substantially equal to each other or may be different from each other. In the example illustrated in FIG. 3, light-emitting surfaces 21 of adjacent light-emitting parts 20 are arranged at a predetermined interval in a top view. Each of a first light-emitting surface interval dx in the X direction and a second light-emitting surface interval dy in the Y direction corresponds to the predetermined interval. From the viewpoint of light emission characteristics of the light source 2, the narrower the first light-emitting surface interval dx and the second light-emitting surface interval dy, the more preferable. However, there are limits to narrow intervals at which the plurality of light-emitting parts 20 can be mounted. In order to obtain both good light emission characteristics and providing narrow intervals with which the plurality of the light-emitting parts 20 can be mounted, the first light emitting surface interval dx and the second light emitting surface interval dy are both preferably 10 μm or more and 50 μm or less. In the example illustrated in FIG. 3, the shape of the light-emitting surface 21-1 in a top view is a substantially rectangular shape. However, the shape of each of the light-emitting surfaces 21 in a top view may be a substantially circular shape or a substantially elliptical shape, or may be a polygonal shape such as a substantially triangular shape or a substantially hexagonal shape.

Each of the light-emitting parts 20 includes a light-emitting element 22, a wavelength conversion member 24 disposed on the light-emitting element 22, and a covering member 25 covering the lateral surfaces of the light-emitting element 22 and the lateral surfaces of the wavelength conversion member 24.

The light-emitting parts 20 including the light-emitting element 22 and the wavelength conversion member 24 can emit mixed color light in which a color of light emitted from the light-emitting element 22 and a color of light emitted from the wavelength conversion member 24 are mixed. The degree of freedom in the color of light emitted from each of the light-emitting parts 20 can be increased by the combination of the light-emitting element 22 and the wavelength conversion member 24. In addition, the light-emitting parts 20 including the covering member 25 can reduce light leaking from the light-emitting parts 20 and the covering member 25, and thus, the light extraction efficiency of the light-emitting parts 20 can be improved.

Further, the light source 2 includes the plurality of light-emitting parts 20, and the covering member 25 integrally holds a plurality of light-emitting elements 22 and a plurality of wavelength conversion members 24. In the example illustrated in FIG. 4, the covering member 25 is disposed between adjacent light-emitting elements 22 and between adjacent wavelength conversion members 24. In this manner, the covering member 25 integrally holds nine light-emitting elements 22 included in the nine light-emitting parts 20 and nine wavelength conversion members 24 included in the nine light-emitting parts 20.

Because the light source 2 includes the plurality of light-emitting parts 20, the amount of light that can be emitted from the light source 2 can be increased. Further, the covering member 25 integrally holds the plurality of light-emitting elements 22 and the plurality of wavelength conversion members 24, and thus the light source 2 can be easily mounted.

The light source 2 will be described in detail. In the example illustrated in FIG. 4, the light-emitting part 20-1 is disposed on the surface on the +Z side of the substrate 1, with the upper surface of the light-emitting part 20-1 serving as the light-emitting surface 21-1 and the surface opposite the light-emitting surface 21-1 serving as a mounting surface. A wavelength conversion member 24 is provided on the surface on the +Z side of a light-emitting element 22. The covering member 25 covers the lateral surfaces of the light-emitting element 22 and the lateral surfaces of the wavelength conversion member 24 except for the upper surface of the wavelength conversion member 24. Light-emitting surfaces 21 of adjacent light-emitting parts 20 of the nine light-emitting parts 20 included in the light source 2 are separated from each other by the covering member 25. The adjacent light-emitting surfaces 2 may be continuous with each other. For example, one wavelength conversion member 24 may cover the entirety of the upper surfaces of a plurality of light-emitting elements 22. In this case, the first light-emitting surface interval dx and the second light-emitting surface interval dy are 0.

At least one pair of positive and negative electrodes 23 are provided on the surface of the light-emitting element 22 opposite the light-emitting surface 21-1.

The light emitting element 22 includes various semiconductors such as group III-V compound semiconductors and group II-VI compound semiconductors. As the semiconductors, nitride-based semiconductors such as In_{X}Al_{Y}Ga_{1-X-Yl N (}0≤X, 0≤Y, X+Y≤1) are preferably used, and InN, AlN, GaN, InGaN, AlGaN, InGaAlN, and the like can also be used. The light emitting element 22 is, for example, an LED or a laser diode (LD). The emission peak wavelength of the light emitting element 22 is preferably 400 nm or more and 530 nm or less, more preferably 420 nm or more and 490 nm or less, and even more preferably 450 nm or more and 475 nm or less, from the viewpoint of emission efficiency, excitation of a wavelength conversion substance, and the like.

The wavelength conversion member 24 is a member having, for example, a substantially rectangular shape in a top view. The wavelength conversion member 24 is disposed so as to cover the upper surface of the light-emitting element 22. The wavelength conversion member 24 includes a wavelength conversion substance that converts a wavelength of at least a portion of light from the light-emitting element 22. The wavelength conversion member 24 can be formed by using a light-transmissive resin material or an inorganic material such as a ceramic or glass. As the resin material, a thermosetting resin such as a silicone resin, a silicone-modified resin, an epoxy resin, an epoxy-modified resin, or a phenol resin can be used. In particular, a silicone resin or a modified resin thereof having high light resistance and heat resistance is preferable. As used herein, the term “light-transmissive” means that 60% or more of the light from the light-emitting element 22 is preferably transmitted. Further, a thermoplastic resin such as a polycarbonate resin, an acrylic resin, a methylpentene resin, or a polynorbornene resin can be used for the wavelength conversion member 24. Further, the wavelength conversion member 24 may include a light diffusing substance in the resin described above. For example, the wavelength conversion member 24 may be a resin material, a ceramic, glass, or the like containing a wavelength conversion substance, a sintered body of a wavelength conversion substance, or the like. Further, the wavelength conversion member 24 may be a multilayer member in which a resin layer is disposed on the surface on the +Z side of a formed body of a resin, a ceramic, glass, or the like.

Examples of a wavelength conversion substance included in the wavelength conversion member 24 include yttrium aluminum garnet based phosphors (for example, (Y, Gd)₃(Al, Ga)₅O₁₂:Ce), lutetium aluminum garnet based phosphors (for example, Lu₃(Al, Ga)₅O₁₂:Ce), terbium aluminum garnet based phosphors (for example, Tb₃(Al, Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, Ca₈MgSi₄O₁₆C₁₂:Eu), silicate based phosphors (for example, (Ba, Sr, Ca, Mg)₂SiO₄:Eu), oxynitride based phosphors such as β-SiAlON based phosphors (for example, (Si, Al)₃(O,N)₄:Eu) and α-SiAlON based phosphors (for example, Ca(Si, Al)₁₂(O,N)₁₆:Eu), nitride based phosphors such as LSN based phosphors (for example, (La, Y)₃Si₆N₁₁:Ce), BSESN based phosphors (for example, (Ba, Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr, Ca) AlSiN₃:Eu), fluoride based phosphors such as KSF based phosphors (for example, K₂SiF₆:Mn), KSAF based phosphors (for example, K₂(Si₁₋ₓAlₓ)F₆₋ₓ:Mn, where x satisfies 0<x<1), and MGF based phosphors (for example, 3.5MgO·0.5MgF₂·GeO₂:Mn), quantum dots having a Perovskite structure (for example, (Cs, FA, MA) (Pb, Sn) (F, Cl, Br, I)₃, where FA and MA represent formamidinium and methylammonium, respectively), II-VI quantum dots (for example, CdSe), III-V quantum dots (for example, InP), and quantum dots having a chalcopyrite structure (for example, (Ag, Cu) (In, Ga) (S, Se)₂). The wavelength conversion substances described above are particles. One of these wavelength conversion substances may be used alone, or two or more of these wavelength conversion substances may be used in combination.

The light source 2 uses a blue LED as the light-emitting element 22. The wavelength conversion member 24 includes a wavelength conversion substance that converts the wavelength of the light emitted from the light-emitting element 22 into the wavelength of yellow. Accordingly, the light source 2 can emit white light. As a light diffusing substance included in the wavelength conversion member 24, titanium oxide, barium titanate, aluminum oxide, silicon oxide, or the like can be used.

The covering member 25 is a member covering the lateral surfaces of the light-emitting element 22 and the lateral surfaces of the wavelength conversion member 24. The covering member 25 directly or indirectly covers the lateral surfaces of the light-emitting element 22 and the lateral surfaces of the wavelength conversion member 24. The upper surface of the wavelength conversion member 24 is exposed through the covering member 25, and is the light-emitting surface 21-1 of the light-emitting part 20-1. The covering member 25 may be separated between adjacent light emitting parts of the nine light-emitting parts 20. To improve the light extraction efficiency, the covering member 25 is preferably formed of a member having a high light reflectance. For example, an organic material such as a resin containing a light reflective substance such as a white pigment can be used for the covering member 25. For example, the covering member 25 may be a light reflective member formed of an inorganic material including boron nitride or alkali metal silicate. In this case, the covering member 25 may further include titanium oxide or zirconium oxide.

Examples of the light reflective substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, silicon oxide, and the like. It is preferable to use one of the above substances alone or a combination of two or more of the above substances. Further, as the resin material, it is preferable to use a base material including a resin material whose main component is a thermosetting resin such as an epoxy resin, an epoxy-modified resin, a silicone resin, a silicone-modified resin, or a phenol resin. The covering member 25 may be configured with a member having light transmissivity or light absorbability with respect to visible light as necessary.

The light-emitting part 20 is electrically connected to wiring 12 of the substrate 1. The substrate 1 preferably includes the wiring 12 at least on the surface of the substrate 1. The substrate 1 may include the wiring 12 inside the substrate 1. The light-emitting part 20 and the substrate 1 are electrically connected to each other by connecting the wiring 12 of the substrate 1 to at least a pair of positive and negative electrodes 23 of the light-emitting part 20 via electrically-conductive members 13. The configuration, the size, and the like of the wiring 12 of the substrate 1 are set in accordance with the configuration, the size, and the like of the electrodes 23 of the light-emitting part 20.

The wiring 12 can be composed of at least one of copper, iron, nickel, tungsten, chromium, aluminum, silver, gold, titanium, palladium, rhodium, or an alloy thereof. In addition, a layer of silver, platinum, aluminum, rhodium, gold, an alloy thereof, or the like may be provided on the surface layer of the wiring 12 from the viewpoint of wettability and/or light reflectivity of the electrically-conductive members 13.

### Modifications of First Embodiment

Modifications of the light-emitting module according to the first embodiment will be described below. The same names and reference numerals as those of the above-described embodiment refer to the same or equivalent members or components, and a detailed description thereof will be omitted as appropriate. The same applies to embodiments and modifications thereof as will be described later.

### First Modification of First Embodiment

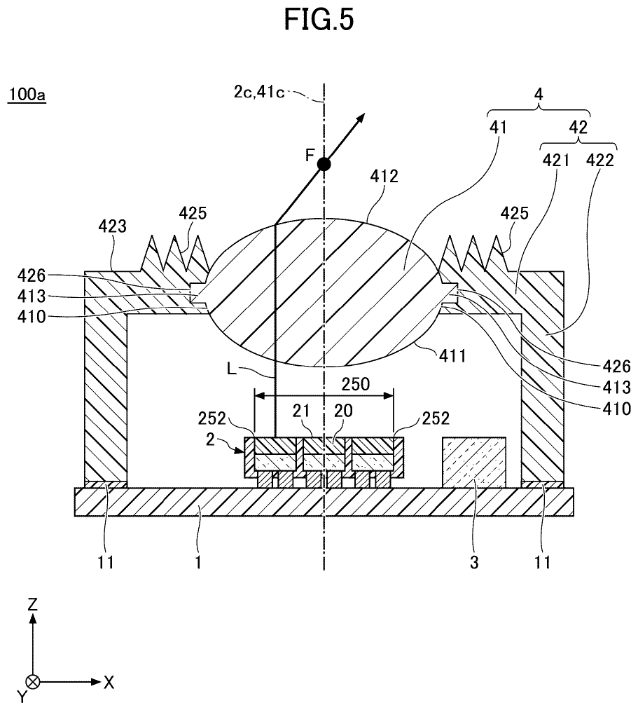

FIG. 5 is a schematic cross-sectional view illustrating a light-emitting module 100a according to a first modification of the first embodiment. The top view of the light-emitting module 100a is substantially the same as the top view of the light-emitting module 100 illustrated in FIG. 1. FIG. 5 schematically illustrates a cross section of the light-emitting module 100a taken through a line corresponding to the line IIA-IIA of FIG. 1.

The first modification mainly differs from the above-described first embodiment in that, at an interface 410 between the first lens 41 and the first support 42, the first lens 41 includes a first joining portion 413, and the first support 42 includes a second joining portion 426 fitted to the first joining portion 413. In the first modification, the term “fit” means that the shape of the first joining portion 413 and the shape of the second joining portion 426 are firmly fitted to each other.

The first joining portion 413 has at least one of a recessed portion or a projection. The second joining portion 426 has at least one of a recessed portion or a projection. In the example illustrated in FIG. 5, the first joining portion 413 has one projection that protrudes in a direction intersecting the optical axis 41c and away from the optical axis 41c. The projection of the first joining portion 413 may protrude in a direction substantially orthogonal to the optical axis 41c. In the example illustrated in FIG. 5, the second joining portion 426 has one recessed portion that is recessed in a direction intersecting the optical axis 41c and away from the optical axis 41c. The recessed portion of the second joining portion 426 may be recessed in a direction substantially orthogonal to the optical axis 41c. The first joining portion 413 may have one or more recesses, one or more projections, or one or more recesses and one or more projections, or may have a rough surface. The second joining portion 426 may have one or more recesses, one or more projections, or one or more recesses and one or more projections, or may have a rough surface, such that the second joining portion 42 can be fitted to the first joining portion 413. The shape of the first joining portion 413 and the shape of the second joining portion 426 can be appropriately changed as long as the first joining portion 413 and the second joining portion 426 can be fitted to each other. If the first joining portion 413 has a projection that protrudes in a direction intersecting the optical axis 41c and approaching the optical axis 41c, there would be a possibility that light emitted from the light source 2 would hit the projection when the light is transmitted through the first lens 41. For this reason, the first joining portion 413 preferably has a projection that protrudes in a direction intersecting the optical axis 41c and away from the optical axis 41c. Accordingly, light emitted from the light source 2 can be suppressed from being blocked by the second joining portion 426 of the first support 42.

In the light-emitting module 100a, the projection of the first joining portion 413 and the recessed portion of the second joining portion 426 are fitted to each other, and thus the contact area between the first lens 41 and the first support 42 can be increased at the interface 410 between the first lens 41 and the first support 42. Accordingly, the adhesion strength between the first lens 41 and the first support 42 manufactured by a double-molding method or the like can be increased, and the mechanical strength of the first light-transmissive member 4 can be increased.

### Second Modification of First Embodiment

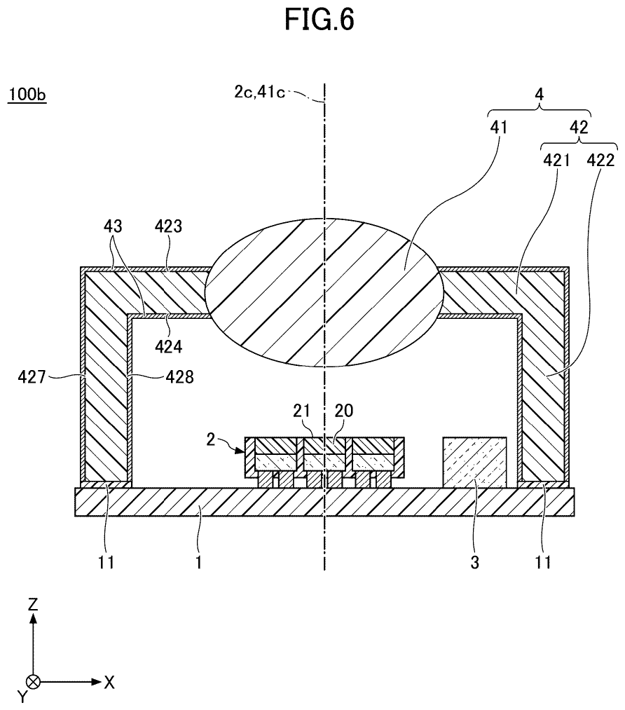

FIG. 6 is a schematic cross-sectional view illustrating a light-emitting module 100b according to a second modification of the first embodiment. The top view of the light-emitting module 100b is substantially the same as the top view of the light-emitting module 100 illustrated in FIG. 1. FIG. 6 schematically illustrates a cross section of the light-emitting module 100b taken through a line corresponding to the line IIA-IIA of FIG. 1.

The second modification differs from the first embodiment mainly in that the first support 42 includes a light diffusing substance 43 disposed on at least one of the upper surface 423 or the lower surface 424 of the first support 42.

In the example illustrated in FIG. 6, the first support 42 includes the light diffusing substance 43 disposed on each of the upper surface 423 and the lower surface 424 of the upper portion 421. In addition, the first support 42 includes the light diffusing substance 43 disposed on each of an outer lateral surface 427 and an inner lateral surface 428 of the first cylindrical portion 422. The first support 42 does not include the light diffusing substance 43 inside the first support 42.

The light diffusing substance 43 can be easily disposed on the upper surface 423 and the lower surface 424 by, for example, allowing the light diffusing substance 43 applied onto the upper surface 423 and the lower surface 424. Therefore, in the present modification, by disposing the light diffusing substance 43 on both the upper surface 423 and the lower surface 424, light diffusivity can be easily imparted to the first support 42. Accordingly, the light-emitting module 100b that can be easily assembled can be provided. Effects of the present modification other than the above are the same as or similar to the effects of the first embodiment. In the present modification, the first support 42 can include the light diffusing substance 43 on at least one of the upper surface 423 or the lower surface 424, and does not have to include the light diffusing substance 43 on the outer lateral surface 427 and the inner lateral surface 428. Further, the first support 42 may include the light diffusing substance 43 inside the first support 42. In addition, in order to make the electronic component 3 in the light-emitting module 100b less likely to be visually recognizable, the light diffusing substance 43 is preferably disposed on the upper surface 423 that is located away from the interior of the light-emitting module 100b as compared to the lower surface 424. Of light entering the inside of the light-emitting module 100b from the outside, light scattered by the light diffusing substance 43 and transmitted through the first support 42 is scattered to a greater degree as the light travels away from the light diffusing substance 43. Therefore, as the distance between the light diffusing substance 43 and the electronic component 3 increases, the scattered light is more likely to hit the electronic component 3, and thus the electronic component 3 is less visually recognizable.

### Second Embodiment

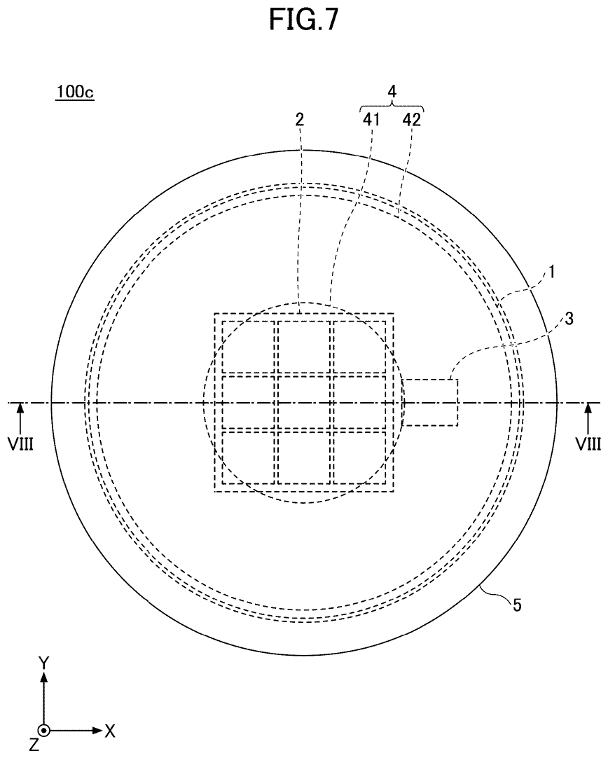

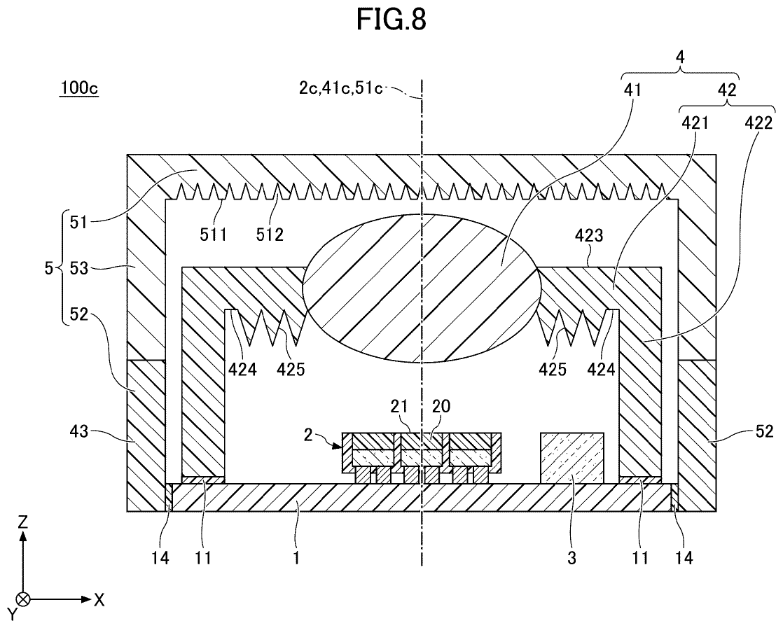

Next, a light-emitting module according to a second embodiment will be described with reference to FIGS. 7 and 8. FIG. 7 is a schematic top view illustrating an example of a light-emitting module 100c according to the second embodiment. FIG. 8 is a schematic cross-sectional view taken through line VIII-VIII of FIG. 7.

As illustrated in FIGS. 7 and 8, the second embodiment differs from the first embodiment mainly in that the light-emitting module 100c includes a second light-transmissive member 5 including a second lens 51 and a second support 52 that supports the second lens 51. The second lens 51 overlaps the first lens 41 in a top view. A first support 42 overlaps the substrate 1 in a top view. At least a portion of the second support 52 is located outward of the substrate 1 in a top view. The light diffusivity of the second support 52 is higher than the light diffusivity of the first lens 41.

The second light-transmissive member 5 is disposed so as to cover the first light-transmissive member 4. In the example illustrated in FIG. 7, the second light-transmissive member 5 has a substantially circular shape in a top view. However, the shape of the second light-transmissive member 5 in a top view may be a substantially elliptical shape, a substantially rectangular shape, a substantially polygonal shape, or the like.

In the example illustrated in FIG. 8, the second light-transmissive member 5 includes the second lens 51, the second support 52, and a second cylindrical portion 53. The second light-transmissive member 5 includes at least one of a resin material such as a polycarbonate resin, an acrylic resin, a silicone resin, or an epoxy resin, or a glass material, which have transmissivity with respect to light emitted from the light source 2. The light transmissivity of the second lens 51 refers to having a light transmittance of preferably 60% or more with respect to light incident on the second lens 51 from the outside.

In the example illustrated in FIGS. 7 and 8, the second lens 51, the second support 52, and the second cylindrical portion 53 are a monolithic member without using an adhesive member. From another viewpoint, the second lens 51 is connected to the second support 52 via the second cylindrical portion 53. However, the second lens 51, the second support 52, and the second cylindrical portion 53 may be separate members bonded to each other by an adhesive member. Further, the second light-transmissive member 5 does not have to include the second cylindrical portion 53, and the second lens 51 and the second support 52 may be directly connected to each other without the second cylindrical portion 53 provided therebetween.

The second lens 51 transmits light emitted from the light source 2 and transmitted through the first lens 41. In the example illustrated in FIG. 8, the second lens 51 has projections 512 on a lower surface 511 thereof. The projections 512 are arranged concentrically around an optical axis 51c of the second lens 51. The optical axis 51c of the second lens 51 overlaps the optical axis 41c of the first lens 41 in a top view. The projections 512 may be a Fresnel lens having a Fresnel shape. The second lens 51 is not limited to a Fresnel lens, and may be a biconvex lens, a plano-convex lens, a biconcave lens, a plano-concave lens, an array lens, a meniscus lens, an aspherical lens, a cylindrical lens, or the like, which is supported by the second cylindrical portion 53, the second support 52, or the like from the outside.

The light-emitting module 100c includes the second lens 51, and thus the light-emitting module 100c can perform light distribution control by using the combination of the first lens 41 and the second lens 51. Accordingly, in the light-emitting module 100c, the degree of freedom in light distribution control can be increased as compared to when only the first lens 41 is included.

The second cylindrical portion 53 is a circular annular portion located outward of the first light-transmissive member 4 in a top view. The second cylindrical portion 53 is provided so as to extend downward at a position outward of the first light-transmissive member 4.

The second support 52 supports the second lens 51 such that the second lens 51 is disposed above the first lens 41. The second support 52 is a circular annular portion located outward of the substrate 1 in a top view. The second support 52 is provided so as to extend downward at a position outward of the substrate 1. The second support 52 is disposed such that a portion of the inner lateral surface of the second support 52 faces the outer lateral surface of the substrate 1, and the portion of the inner lateral surface of the second support 52 and the outer lateral surface of the substrate 1 are bonded to each other by an adhesive member 14. The second light-transmissive member 5 is bonded to the substrate 1 by bonding the second support 52 to the substrate 1.

In the example illustrated in FIGS. 7 and 8, the second support 52 includes a light diffusing substance 43 inside the second support 52. In the light-emitting module 100c, by making the second support 52 include the light diffusing substance 43 inside the second support 52, light diffusivity can be easily imparted to the second support 52. However, the light diffusing substance 43 may be placed on at least one of the outer lateral surface or the inner lateral surface of the second support 52. The light diffusivity of the second support 52 is higher than the light diffusivity of the first lens 41. The light diffusivity of the second support 52 being higher than the light diffusivity of the first lens 41 means that, for example, the haze value of the second support 52 is higher than the haze value of the first lens 41. The haze value of the second support 52 is 10% or more and 90% or less. The haze value of the first lens 41 is less than 10%, and is preferably 5% or less. Further, the light diffusivity of the second support 52 is higher than the light diffusivity of the second lens 51. The light diffusivity of the second support 52 being higher than the light diffusivity of the second lens 51 means that, for example, the haze value of the second support 52 is higher than the haze value of the second lens 51. The haze value of the second support 52 is 10% or more and 90% or less. The haze value of the second lens 51 is less than 10%, and is preferably 5% or less. At least one of the first lens 41 or the second lens 51 may include a resin containing a light diffusing substance 43. In this case, the content of the light diffusing substance 43 in the first lens 41 or the second lens 51 is smaller than the content of the light diffusing substance 43 in the second support 52. Further, in the present embodiment, the light transmittance of the second support 52 is lower than the light transmittance of the first support 42. Further, the haze value of the second support 52 is higher than the haze value of the first support 42.

In the light-emitting module 100c, the substrate 1 is located below the first support 42 in a top view, and thus members and components disposed below (on the −Z side of) the substrate 1 are not visually recognizable. However, there is a region where the substrate 1 is not located below the second support 52. In such a case, if members and components included in a housing of a smartphone and disposed below a second support 52 are visually recognizable from the outside through a second cylindrical portion 53, the aesthetic appearance of a light-emitting module would be degraded. Conversely, in the light-emitting module 100c, the second support 52 has light diffusivity, and the light diffusivity of the second support 52 is higher than the light diffusivity of the first lens 41, and thus, members and components disposed below the second support 52 are less visually recognizable in a top view. Accordingly, the aesthetic appearance of the light-emitting module 100c can be improved. The light diffusivity of the second support 52 may be equal to the light diffusivity of the first support 42, or may be higher than the light diffusivity of the first support 42.

In the example illustrated in FIGS. 7 and 8, the second lens 51, the second cylindrical portion 53, and the second support 52 constitute a formed body in which the second cylindrical portion 53 and the second support 52 are directly bonded to each other at the interface between the second cylindrical portion 53 and the second support 52. More specifically, the second lens 51 and the second cylindrical portion 53 include a resin having light transmissivity. The second support 52 has light transmissivity and includes a resin containing the light diffusing substance 43. In the second support 52, the resin that serves as a base material and includes the light diffusing substance 43 may be the same as or different from the resin constituting the second lens 51 and the second cylindrical portion 53. The second lens 51, the second cylindrical portion 53, and the second support 52, which constitute the formed body in which the second cylindrical portion 53 and the second support 52 are directly bonded to each other at the interface between the second cylindrical portion 53 and the second support 52, can be manufactured by, for example, double-molding. The light-emitting module 100c can be easily assembled by using the second lens 51, the second cylindrical portion 53, and the second support 52, which constitute the formed body in which the second cylindrical portion 53 and the second support 52 are directly bonded to each other at the interface therebetween. If the second light-transmissive member 5 does not include the second cylindrical portion 53, the second lens 51 and the second support 52 can constitute a formed body in which the second lens 51 and the second support 52 are directly bonded to each other at the interface between the second lens 51 and the second support 52.

Further, in the example illustrated in FIG. 8, the first support 42 has three annular projections 425 on the lower surface 424 of the upper portion 421. Each of the three annular projections 425 is a portion that protrudes from the lower surface 424 toward the side (for example, the −Z side) on which the light source 2 is located. The three annular projections 425 are arranged concentrically around the optical axis 41c of the first lens 41. The three concentric annular projections 425 may have, for example, a Fresnel shape. Effects of the first support 42 including the three annular projections 425 on the lower surface 424 of the upper portion 421 are the same as or similar to the effects of the first support 42 including the three annular projections 425 on the upper surface 423 of the upper portion 421 described in the first embodiment.

### Third Embodiment

Next, a smartphone according to a third embodiment will be described.

### Example Configuration of Smartphone According to Third Embodiment

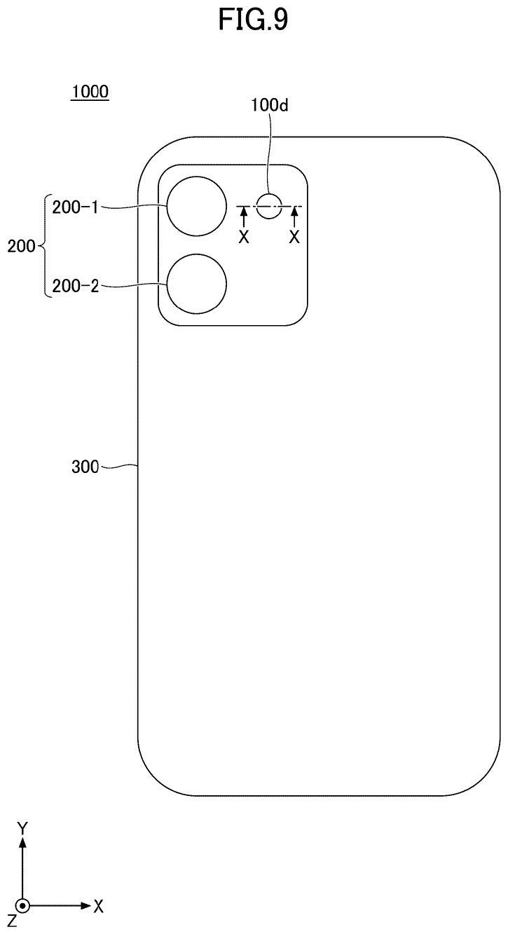

FIG. 9 is a schematic rear view illustrating an example of a smartphone 1000 according to the third embodiment.

As an example, a light-emitting module 100d is included in a smartphone. The light-emitting module 100d installed in the smartphone is a light-emitting module used as a flash light source when an imaging device provided in the smartphone captures an image.

In the example illustrated in FIG. 9, the smartphone 1000 includes the light-emitting module 100d, an imaging device 200, and a housing 300. The imaging device 200 includes an imaging device 200-1 and an imaging device 200-2. The imaging device includes a camera for capturing a still image and a video camera for capturing a moving image. The light-emitting module 100d and the imaging device 200 are arranged so as to be partially exposed through the rear surface of the smartphone 1000. The rear surface of the smartphone 1000 is opposite to the front surface on which a display part configured with an organic electroluminescence (EL) display, a liquid crystal panel, or the like is disposed.

Light emitted from the light-emitting module 100d is used to irradiate a subject when the subject is captured by each of the imaging device 200-1 and the imaging device 200-2. The smartphone 1000 does not have to include the light-emitting module 100d, and may include at least one of the light-emitting module 100, the light-emitting module 100a, the light-emitting module 100b, the light-emitting module 100c, or the light-emitting module 100d.

In the smartphone 1000, because at least one of the light-emitting module 100a, the light-emitting module 100b, the light-emitting module 100c, or the light-emitting module 100d is a flash light source, a light-emitting module for a flash can be easily assembled. In addition, in the present embodiment, a light-emitting module included in the smartphone 1000 is at least one of the light-emitting module 100, the light-emitting module 100a, the light-emitting module 100b, the light-emitting module 100c, or the light-emitting module 100d, and thus the smartphone 1000 including such a light-emitting module can be easily assembled.

The imaging device 200 includes a camera for capturing a still image and a video camera for capturing a moving image. Specifications of the imaging device 200-1 and specifications of the imaging device 200-2 may be the same or different from each other. For example, a specification such as imaging resolution or an imaging angle of view may be different between the imaging device 200-1 and the imaging device 200-2. The imaging device 200 may include one or more imaging devices. The arrangement of the imaging device 200 and the light-emitting module 100d can be appropriately changed according to specifications needed for the smartphone 1000.

The housing 300 is a box-shaped member in which the light-emitting module 100d, the imaging device 200, their control boards, and the like are housed. A resin material, a metal material, or the like can be used as a material constituting the housing 300. Further, the size, the shape, or the like of the housing 300 can be appropriately changed according to specifications needed for the smartphone 1000.

### Example Configuration of Light-Emitting Module 100d

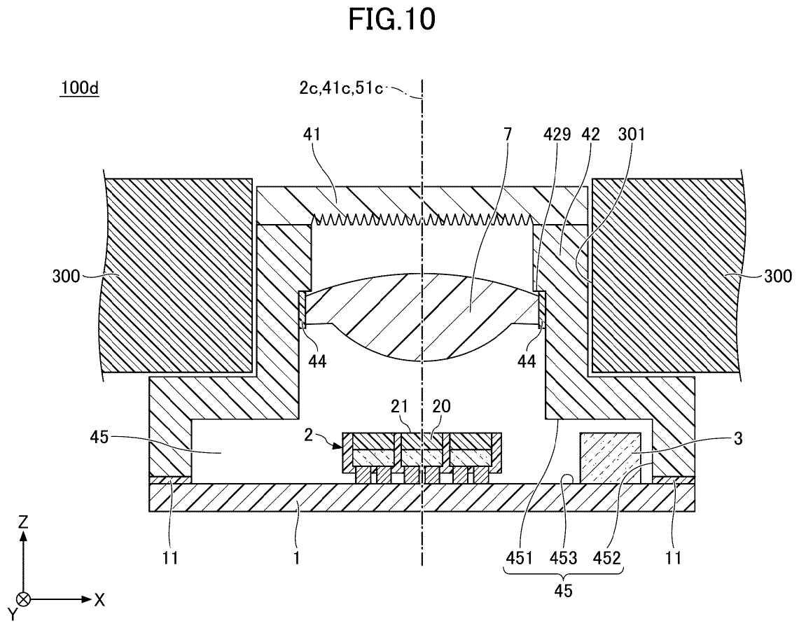

FIG. 10 is a schematic cross-sectional view illustrating an example of the light-emitting module 100d. FIG. 10 schematically illustrates a cross section taken through line X-X of FIG. 9.

In the light-emitting module 100d, a portion of a first support 42 and a portion of the substrate 1 define a recessed portion 45 having an upper surface 451, a lateral surface 452, and a bottom surface 453. The electronic component 3 is disposed in the recessed portion 45. The recessed portion 45 overlaps the housing 300 of the smartphone 1000 in a top view.

In the light-emitting module 100d, the recessed portion 45 in which the electronic component 3 is disposed overlaps the housing 300 of the smartphone 1000 in a top view, and thus the electronic component 3 can be less visually recognizable from the outside of the smartphone 1000. Accordingly, the aesthetic appearance of the smartphone 1000 can be improved. In addition, the electronic component 3 is disposed in the recessed portion 45 partially defined by the first support 42 that has high light diffusivity, and thus the electronic component 3 can be even less visually recognizable from the outside of the light-emitting module 100d. Accordingly, the aesthetic appearance of the light-emitting module 100d can be improved. Effects of the light-emitting module 100d other than the above are the same as or similar to those of the light-emitting module 100.

In the light-emitting module 100d, a first lens 41 has a plurality of projections on the lower surface thereof, and the plurality of projections are concentrically arranged around an optical axis 41c of the first lens 41. The upper surface of the first lens 41 is a flat surface. The first lens 41 may be a Fresnel lens. In the example illustrated in FIG. 10, the light-emitting module 100d includes a third lens 7 below the first lens 41. The first support 42 supports the third lens 7 by allowing the third lens 7 to be bonded to the inner lateral surface of the first support 42 with an adhesive member 44. In addition, the first support 42 supports the first lens 41 by being continuous with the first lens 41 without using an adhesive member. In the light-emitting module 100d, the first support 42 has light diffusivity. In the example illustrated in FIG. 10, the third lens 7 is a biconvex lens having two convex surfaces respectively protruding toward the side (−Z side) on which the light source 2 is located and the side (+Z side) opposite to the side on which the light source 2 is located. As used herein, “supporting a lens” includes directly supporting and fixing the lens by contacting the lens and indirectly supporting and fixing the lens via a member.

In the light-emitting module 100d, the first lens 41 and a portion of the first support 42 are disposed within an opening 301 of the housing 300. In the light-emitting module 100d, the upper surface of the first lens 41 is exposed through the housing 300. In the light-emitting module 100d, the housing 300 is disposed adjacent to the outer lateral surface of the first support 42. Because the first support 42 is disposed adjacent to the inner lateral surface of the housing 300, when the housing 300 is viewed from the outside of the light-emitting module 100d through the inner lateral surface of the first support 42, the color of the housing 300 can be suppressed from being seen through, and thus the aesthetic appearance of the light-emitting module 100d can be improved.

In the example illustrated in FIG. 10, the first support 42 is bent in a direction intersecting the optical axis 41c of the first lens 41 and away from the optical axis 41c, and thus the surface of the first support 42 facing the upper surface of the substrate 1 serves as the upper surface 451 of the recessed portion 45. Further, the inner lateral surface of a portion of the first support 42 serve as the lateral surface 452 of the recessed portion 45. A portion of the upper surface of the substrate 1, facing the upper surface 451, serves as the bottom surface 453. The recessed portion 45 has an outer edge shape such that the lateral surface 452 of the recessed portion 45 is formed in a circular annular shape in a top view. The outer edge shape of the upper surface 451 and the outer edge shape of the bottom surface 453 of the recessed portion 45 are also circular annular shapes such that the light source 2 is disposed inside the recessed portion 45 in a top view. Therefore, each of the upper surface 451 and the bottom surface 453 of the recessed portion 45 has a circular annular shape as a whole in a top view. However, the outer edge shape of the lateral surface 452 of the recessed portion 45 in a top view may be a rectangular annular shape or the like other than the circular annular shape in accordance with the shape of the light-emitting module 100d.

The third lens 7 is fixed at a first connection surface 429 and the inner lateral surface of the first support 42. The first connection surface 429 is continuous with the inner lateral surface of the first support 42 and has an annular shape in a top view. The first connection surface 429 may be a continuous surface or may include a plurality of surfaces arranged intermittently, as long as the third lens 7 can be fixed.

The third lens 7 may be bonded to the first support 42 by using ultrasonic waves. In the case of using ultrasonic bonding, the third lens 7 is fixed at the first connection surface 429. For example, a region where the third lens 7 and the first support 42 are bonded is heated by irradiating the region with ultrasonic waves. At least one of the third lens 7 or the first support 42 is melted by heating, and is cooled and cured after being melted, thereby allowing the third lens 7 and the first support 42 to be bonded. Using ultrasonic waves to bond the third lens 7 and the first support 42 can eliminate the need for a bonding process using the adhesive member 44, and thus the light-emitting module 100d can be easily assembled.

The third lens 7 is not limited to a biconvex lens, and may be a lens including a plurality of concentric projections.

### Modifications of Third Embodiment

Modifications of the light-emitting module included in the smartphone according to the third embodiment will be described.

### First Modification of Third Embodiment

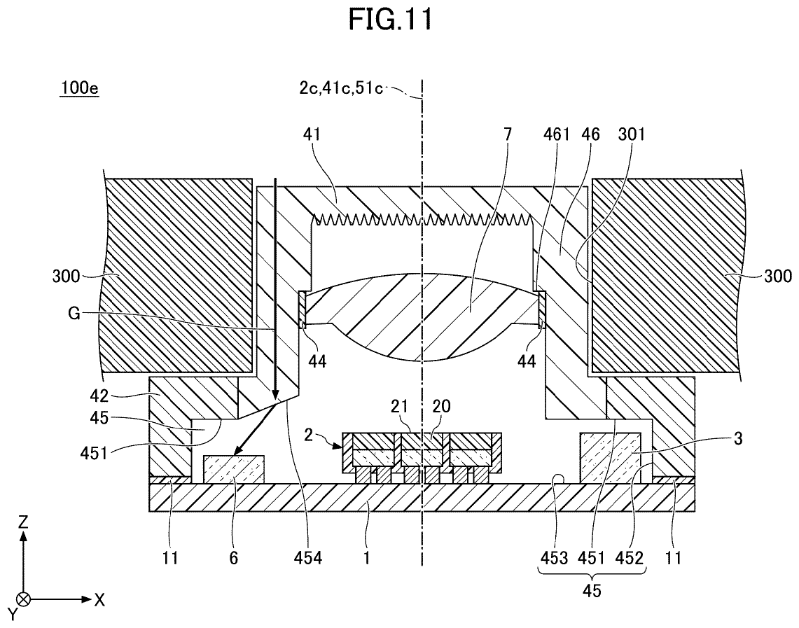

FIG. 11 is a schematic cross-sectional view illustrating a first modification of the light-emitting module included in the smartphone according to the third embodiment. FIG. 11 schematically illustrates a cross section taken through a line corresponding to the line X-X of FIG. 9.

A light-emitting module 100e according to the first modification includes a third support 46. The third support 46 supports the third lens 7 by the third lens 7 being bonded to the inner lateral surface of the third support 46 with an adhesive member 44. In addition, the third support 46 supports the first lens 41 by being continuous with the first lens 41 without an adhesive surface interposed between the third support 46 and the first lens 41. The third support 46 is continuous with a first support 42. The lower surface of the third support 46 and a portion of the lower surface of the first support 42 constitute an upper surface 451 of a recessed portion 45.

In the example illustrated in FIG. 11, the light-emitting module 100e includes an external light sensor 6 disposed on the substrate 1 and separated from the light source 2 and the electronic component 3. The electronic component 3 is a Zener diode used to protect the light source 2. The external light sensor 6 is disposed in the recessed portion 45. In a top view, the external light sensor 6 disposed in the recessed portion 45 overlaps the housing 300 of the smartphone 1000. In addition, the upper surface 451 of the recessed portion 45 in the vicinity of the external light sensor 6 has an inclined portion 454 inclined with respect to the upper surface 451. As described above, the external light sensor 6 is included in the electronic component 3, however, in the first modification of the third embodiment, the electronic component 3 and the external light sensor 6 are distinguished from each other for the sake of description.

The external light sensor 6 is used to detect brightness around the light-emitting module 100e. A photo diode (PD) or the like can be used as the external light sensor 6. The external light sensor 6 receives external light that has entered the light-emitting module 100e from the outside of the light-emitting module 100e, and outputs an electric signal corresponding to the intensity of the external light to a control board or the like that controls the operation of the light-emitting module 100e. The control board can control the amount of light emitted from the light-emitting module 100e according to the electric signal input from the external light sensor 6. Using the control board can enable the smartphone 1000 to emit a large amount of light from the light-emitting module 100e when the surroundings of the light-emitting module 100e are dark, and to emit a small amount of light from the light-emitting module 100e when the surroundings of the light-emitting module 100e are bright. Accordingly, the smartphone 1000 can allow the imaging device 200 to capture an image with an appropriate exposure.

The third lens 7 is fixed at a second connection surface 461 that is continuous with the inner lateral surface of the third support 46 and that has an annular shape in a top view. The second connection surface 461 may be a continuous surface or may include a plurality of surfaces arranged intermittently, as long as the third lens 7 can be fixed. In the case of using ultrasonic bonding, the third lens 7 is fixed at the second connection surface 461.

The transmissivity of the third support 46 is preferably substantially equal to the transmissivity of the first lens 41. By making the transmissivity of the third support 46 substantially equal to the transmissivity of the first lens 41, light is easily transmitted through the third support 46, and thus the amount of external light received by the external light sensor 6 increases. Accordingly, the external light sensor 6 can detect external light with higher accuracy.

The inclined portion 454 refracts external light G enters into the third support 46 from the outside of the light-emitting module 100f and transmitted through the inside of the third support 46. The inclined portion 454 can guide the external light G to the external light sensor 6 disposed at a position overlapping the housing 300 of the smartphone 1000 in a top view by refracting the external light G.

The external light sensor 6 receives the guided external light G, and thus the brightness of the external light G can be detected with high accuracy. For example, the brightness of the external light G can be detected with higher accuracy by increasing the signal-to-noise (SN) ratio of the external light G. Accordingly, in the light-emitting module 100e, while the external light sensor 6 can be less visually recognizable from the outside of the light-emitting module 100e, the accuracy of detecting the brightness of the external light G by the external light sensor 6 can be improved.

Because the housing 300 overlaps the electronic component 3 and the external light sensor 6, the electronic component 3 and the external light sensor 6 are less visually recognizable from the outside of the light-emitting module 100e. Therefore, in the light-emitting module 100e, the first support 42 does not have to have light diffusivity. Further, the transmissivity of the first support 42 may be substantially equal to the transmissivity of the first lens 41 or higher than the transmissivity of the first lens 41.

Effects of the light-emitting module 100e other than the above are the same as or similar to those of the light-emitting module 100d.

### Second Modification of Third Embodiment

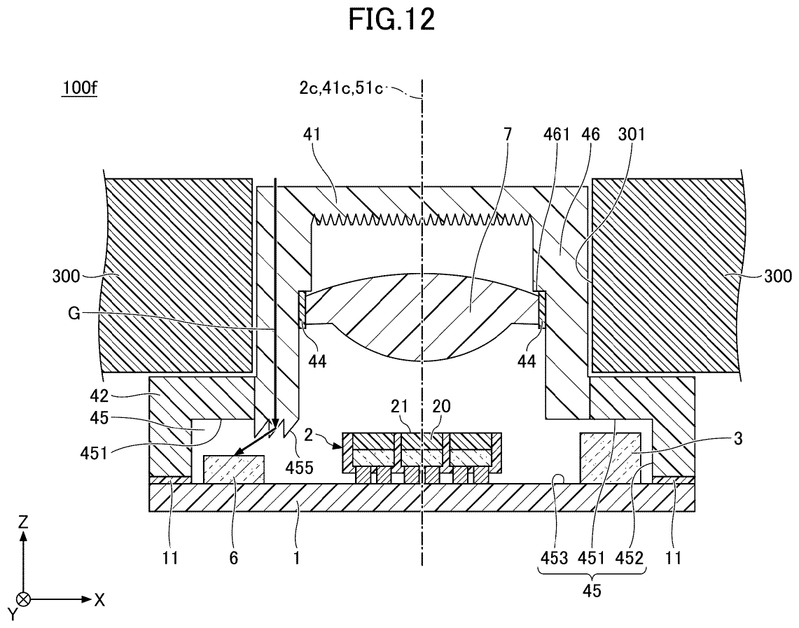

FIG. 12 is a schematic cross-sectional view illustrating a second modification of the light-emitting module included in the smartphone according to the third embodiment. FIG. 12 schematically illustrates a cross section taken through a line corresponding to the line X-X of FIG. 9.

A light-emitting module 100f according to the second modification differs from the light-emitting module 100e in that the light-emitting module 100f includes a total reflection portion 455 provided at an upper surface 451 of a recessed portion 45 in which the external light sensor 6 is disposed.

The total reflection portion 455 is a portion having a total reflection surface and protruding from the upper surface 451 toward the substrate 1. In the example illustrated in FIG. 12, the total reflection portion 455 has three portions protruding from the upper surface 451 toward the substrate 1. However, the number of protruding portions included in the total reflection portion 455 is not limited to three, and can be appropriately changed.

The total reflection portion 455 totally reflects, at the total reflection surface, external light G entering into the third support 46 from the outside of the light-emitting module 100f and transmitted through the inside of the third support 46. By totally reflecting the external light G at the total reflection surface, the total reflection portion 455 can guide the external light G to the external light sensor 6 disposed at a position overlapping the housing 300 of the smartphone 1000 in a top view.

The external light sensor 6 receives the guided external light G, and thus the brightness of the external light G can be detected with high accuracy. For example, the brightness of the external light G can be detected with higher accuracy by increasing the signal-to-noise (SN) ratio of the external light G. Accordingly, in the light-emitting module 100f, while the external light sensor 6 can be less visually recognizable from the outside of the light-emitting module 100f, the accuracy of detecting the brightness of the external light G by the external light sensor 6 can be improved.

Effects of the light-emitting module 100f other than the above are the same as or similar to those of the light-emitting module 100d.

Although embodiments have been described in detail above, the above-described embodiments are non-limiting examples, and various modifications and substitutions can be made to the above-described embodiments without departing from the scope described in the claims.

The numbers such as ordinal numbers and quantities used in the description of the embodiments are all exemplified to specifically describe the technique of the present disclosure, and the present disclosure is not limited to the exemplified numbers. In addition, the connection relationship between the components is illustrated for specifically describing the technique of the present disclosure, and the connection relationship for implementing the functions of the present disclosure is not limited thereto.

The light-emitting modules according to the present disclosure can be easily assembled. Therefore, the light-emitting modules according to the present disclosure can be suitably used for lighting, camera flashes, vehicle headlights, and the like. However, the application of the light-emitting modules according to the present disclosure is not limited to these applications.

According to one embodiment of the present disclosure, a light-emitting module that can be easily assembled can be provided.

What is claimed is:

1. A light-emitting module comprising:
a substrate;
a light source disposed on the substrate;
an electronic component disposed on the substrate and separated from the light source; and
a first light-transmissive member comprising a first lens and a first support, and covering the light source and the electronic component, the first support supporting the first lens and comprising a light diffusing substance, wherein
a light diffusivity of the first support is higher than a light diffusivity of the first lens, and
the first lens overlaps the light source and the first support overlaps the electronic component in a top view.

2. The light-emitting module according to claim 1, wherein the light diffusing substance included in the first support is disposed on at least one of an upper surface or a lower surface of the first support.

3. The light-emitting module according to claim 1, wherein the first support comprises the light diffusing substance inside the first support.

4. The light-emitting module according to claim 3, wherein the first lens and the first support constitute a formed body in which the first lens and the first support are bonded to each other at an interface between the first lens and the first support.

5. The light-emitting module according to claim 4, wherein, at the interface between the first lens and the first support, the first lens comprises a first joining portion and the first support comprises a second joining portion fitted to the first joining portion.

6. The light-emitting module according to claim 1, wherein the first support overlaps an outer edge of a light emission region of the light source in the top view.

7. The light-emitting module according to claim 1, wherein the first support comprises an annular projection on at least one of an upper surface or a lower surface of the first support.

8. The light-emitting module according to claim 1, wherein:
the first lens is a biconvex lens, and
a distance between a surface of the first lens on a light source side and the light source increases as a distance from an optical axis of the first lens increases.

9. The light-emitting module according to claim 1, further comprising:
a second light-transmissive member comprising a second lens, and a second support that supports the second lens, wherein:
the second lens overlaps the first lens in the top view,
the first support overlaps the substrate in the top view,
at least a portion of the second support is located outward of the substrate in the top view, and
a light diffusivity of the second support is higher than the light diffusivity of the first lens.

10. The light-emitting module according to claim 1, wherein
the light source comprises at least one light-emitting part, which comprises:
a light-emitting element,
a wavelength conversion member disposed above the light-emitting element, and
a covering member covering a lateral surface of the light-emitting element and a lateral surface of the wavelength conversion member.

11. The light-emitting module according to claim 1, wherein:
the light source comprises a plurality of light-emitting parts, each light-emitting part comprising:
a light-emitting element, and
a wavelength conversion member disposed above the light-emitting element, and
the light-emitting module further comprises a covering member that integrally holds the light-emitting elements and the wavelength conversion members and covers lateral surfaces of the light-emitting elements and lateral surfaces of the wavelength conversion members.

12. The light-emitting module according to claim 1, wherein the light-emitting module is a flash light source.

13. A smartphone comprising:
the light-emitting module of claim 1.

14. The smartphone according to claim 13, further comprising:
a housing, wherein:
a portion of the first support and a portion of the substrate constitute a recessed portion having an upper surface, a lateral surface, and a bottom surface,
the electronic component is disposed in the recessed portion, and
the recessed portion overlaps the housing in the top view.
